(19) United States
(12) Patent Application Publication
(10) Pub. No.: US 2022/0292272 A1
(43) Pub. Date: Sep. 15, 2022

(54) A METHOD AND A SYSTEM FOR STORING INFORMATION ITEMS

(71) Applicant: Somark Group Ltd, SYDNEY, New South Wales (AU)

(72) Inventors: Adrian Knight, SYDNEY, New South Wales (AU); Paul Donohoe, SYDNEY, New South Wales (AU)

(73) Assignee: Somark Group Ltd, SYDNEY, New South Wales (AU)

(21) Appl. No.: 16/755,323

(22) PCT Filed: Oct. 12, 2018
(86) PCT No.: PCT/AU2018/051110

§ 371 Date: Apr. 10, 2020

Related U.S. Application Data
(60) Provisional application No. 62/571,758, filed on Oct. 12, 2017.

(51) Int. Cl. G06K 7/10; G06K 19/077

(52) U.S. Cl. CPC G06K 7/10366; G06K 19/07758

(57) ABSTRACT

Disclosed herein is a system (10) for storing a plurality of information items on a radio frequency identification (RFID) tag (12). In this but not all embodiments, the RFID tag (12) is attached to an animal (15). The system (10) comprises a processor (12). The processor (12) comprises non-transitory processor readable tangible media in the form of flash memory (14) including program instructions which when executed by the processor (12) causes the processor to perform an embodiment of a method. Also disclosed herein is a method for storing information items.

### TECHNICAL FIELD

The disclosure herein generally relates to a method and a system for storing information items, and particularly but not exclusively to storing information in radio frequency identification (RFID) tag memory.

### BACKGROUND

Research may be conducted at an animal research facility, which may be in the form of an animal research laboratory. For example, pharmaceutical research may be conducted using a plurality of rodents in the form of rats or mice, or generally any suitable form of animal. A schematic diagram of an example of an animal research facility is shown in FIG. 1, and is generally indicated by the numeral 1. The animal research facility 1 comprises a plurality of racks 2, each supporting a plurality of animal enclosures. The animal research facility 1 comprises a plurality of animals distributed between the plurality of animal enclosures. There may be many animals in any one of the plurality of animal enclosures. The animal research facility 1 may also comprise one or more benches 3 for a plurality of research stations 4, 5, 6 for example weigh scale station 4, and animal dosing station 5.

Animal research facilities may comprise thousands of animals, and thousands of enclosures. Currently, animals may have identification ear notches or tags having printed identification information. The identity of animals may be manually obtained by inspecting ear identification notches or attached tags. The identity of the animal in an enclosure may be manually recorded, for example on records in the form of enclosure cards attached to a plurality of enclosures.

Manually determining animal identity and recording thereof is prone to error. To obtain information indicative of a characteristic of the animal, for example it's genotype, a record associated with the identity information for the animal may be consulted. In determining the characteristic of the animal, human error may occur when the identity is determined, and also when the associated record is identified and subsequently read. This may result in corruption of an experiment, which is costly, time consuming, and/or result in the euthanasia of the animal. Some research rodents, for example, may cost approximately $1000 each. Incorrect protocols (e.g. dosing, weighing etc) may be employed on a misidentified animal. Medical treatments may subsequently be delayed in reaching people in need.

### SUMMARY

Disclosed herein is a system for storing a plurality of information items on a radio frequency identification (RFID) tag.

Disclosed herein is a method. The method comprises the step of electronically selecting a plurality of information items from an electronic data store. The method comprises the step of electronically determining a plurality of compressed code values for the electronically selected plurality of information items. The method comprises the step of sending, for writing to a memory of a radio frequency identification (RFID) tag, the plurality of compressed code values arranged as defined by a memory map, and index information identifying the plurality of compressed code values and the memory map.

Disclosed herein is a method. The method comprises the step of a user interacting with a user interface for an electronic data store to select a set of animals from a plurality of animals, and a plurality of characteristic types for which values are stored in the electronic data store for each animal of the set of animals. The method comprises the step of, for each animal of the set of animals, electronically looking up a plurality of compressed code values for a plurality of values for the plurality of characteristic types for that animal. The method comprises the step of, for each animal, sending, for writing to a memory of a radio frequency identification (RFID) tag attached to the animal, the plurality of compressed code values arranged as defined by a memory map, and index information identifying the plurality of compressed code values and the memory map.

Disclosed herein is non-transitory processor readable tangible media including program instructions which when executed by a processor causes the processor to perform a method disclosed above.

Disclosed herein is a computer program for instructing a processor, which when executed by the processor causes the processor to perform a method disclosed above.

Any of the various features of each of the above disclosures, and of the various features of the embodiments described below, can be combined as suitable and desired.

### BRIEF DESCRIPTION OF THE FIGURES

Embodiments will now be described by way of example only with reference to the accompanying figures in which:

FIG. 1 shows a schematic diagram of a prior art animal research facility comprising a plurality of animals.

FIG. 2 shows a schematic diagram of an animal having attached thereoto an RFID tag, and an embodiment of a system for storing a plurality of information items on a radio frequency identification tag.

FIG. 3 shows a flow chart for an embodiment of a method that may be performed using the system of FIG. 2.

FIG. 4 shows a schematic diagram of another embodiment of a system 10 for storing a plurality of information items on the RFID tag.

FIG. 5 shows a flow chart for another embodiment of a method that may be performed using the system of FIG. 4.

FIG. 6 shows a bit-wise representation of a memory map 61 for a particular selection of information items.

FIG. 7 shows a schematic representation of an example of a cloud virtual server architecture.

FIG. 8 shows a schematic diagram of an example of an integration architecture for the cloud virtual server of FIG. 6.

FIG. 9 shows a schematic diagram of an embodiment of the RFID tag reader.

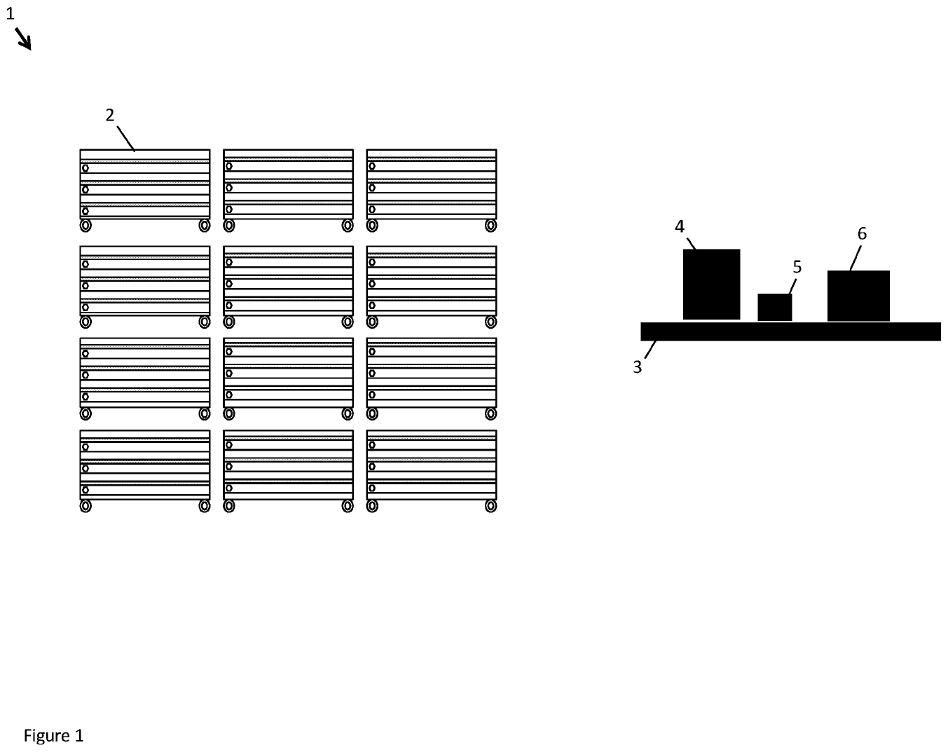

### DESCRIPTION OF EMBODIMENTS

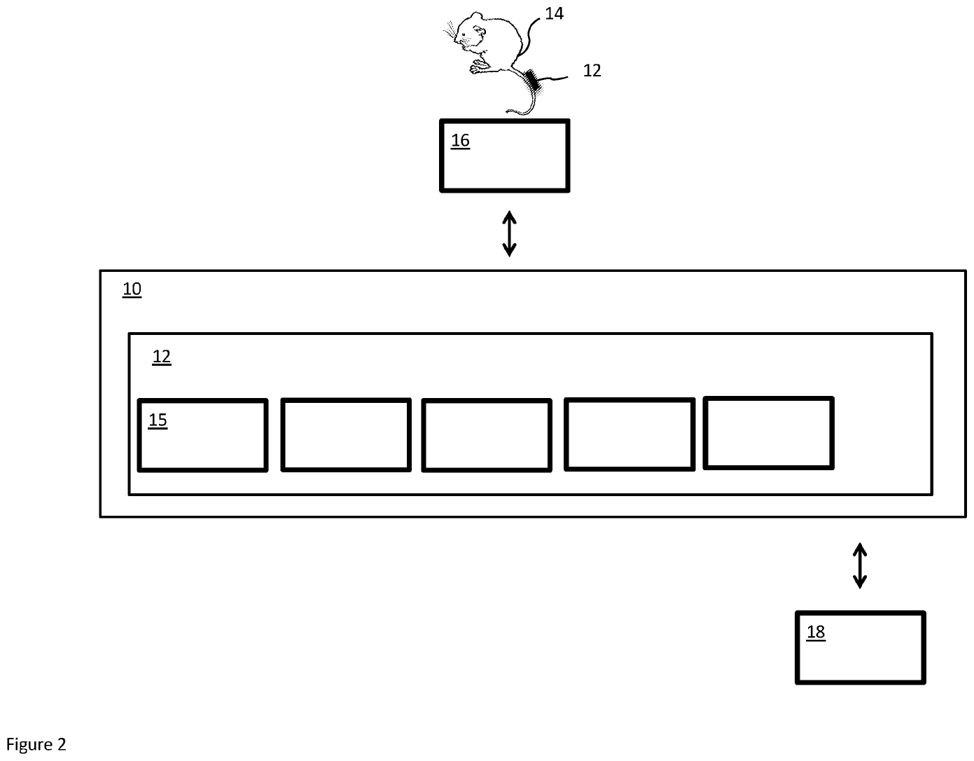

FIG. 2 shows a schematic diagram of an embodiment of a system 10 for storing a plurality of information items on a radio frequency identification (RFID) tag 12. In this but not all embodiments, the RFID tag 12 is attached to an animal in the form of a rodent, and the RFID tag 12 is implanted in the rodent 15. The system 10 comprises a processor 12 in the form of a computational device. The computational device comprises non-transitory processor readable tangible media in the form of flash memory 14 including program instructions which when executed by the processor 12 causes the processor to perform an embodiment of a method.

The processor 12 is in communication with a radio frequency identification (RFID) tag reader 16. The processor is configured to send information to the RFID reader 16. The processor 12 is configured to receive information from the RFID reader 16.

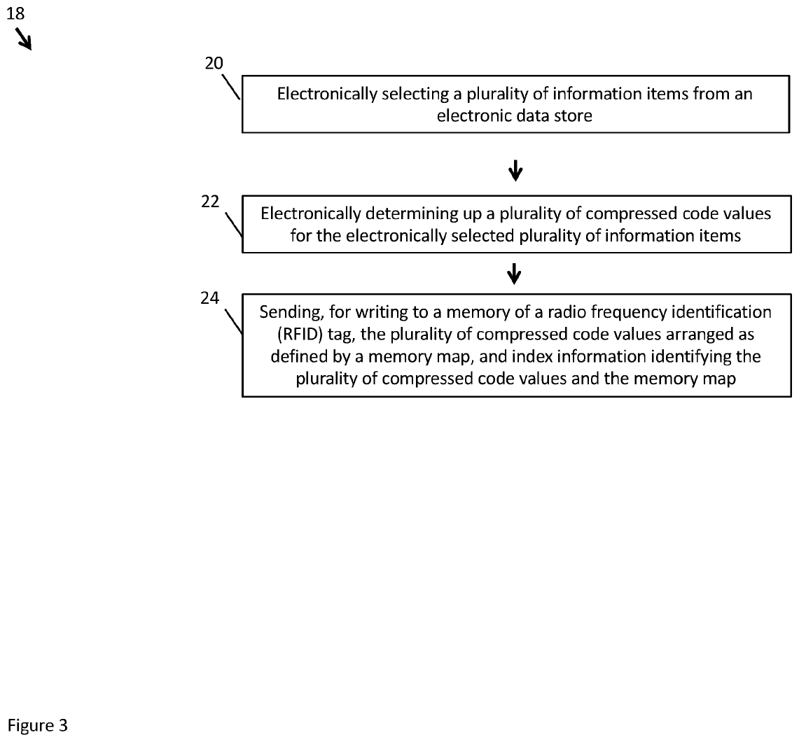

FIG. 3 shows a flow chart for the embodiment of the method 18 performed by the processor 12 when the program instructions are executed. The method comprises a plurality of steps indicated by numerals 20, 22, 24. In a step 20, a plurality of information items from an electronic data store are electronically selected. In a step 22, a plurality of compressed code values for the electronically selected plurality of information items are electronically determined. In a step 24, the plurality of compressed code values arranged as defined by a memory map, and index information identifying the plurality of compressed code values and the memory map are sent.

The RFID tag 12 comprises memory. In this embodiment, the plurality of compressed code values arranged as defined by the memory map, and the index information (“the information”), is sent to the RFID tag reader 16 for writing to the memory of the radio frequency identification tag 12. The system 10 may also send instructions to the RFID tag reader 16 to write the information., or this may be done by another system that receives the sent information. The memory of the RFID tag 12 may be read by the RFID tag reader 16 to obtain identity information indicative of the identity of the thing 14 to which the RFID tag 12 is attached. The identity information is sent by the RFID tag reader 16. The system 10 receives the identity information and confirms that the plurality of information items to be written are associated with the identity information. For example, the data store 18 may comprise a computer database comprising a plurality of records for a plurality of things. Each record may comprise a plurality of fields for characteristics of the thing, for example identify information, gender information, strain information, protocol information, and identity information indicative of the identity of the enclosure in which the thing is housed. The system 10 confirms that the identity information received from the RFID tag reader 16 corresponds the identity information in the record for the plurality of information items to be written to the RFID tag 12 by the RFID tag reader 16 prior to information being written.

The processor 12 is configured to receive the information, for example when retrieved from the RFID tag 12 by the RFID reader 16. The plurality of information items are determinable using the plurality of compress code values arranged as defined by the memory map and the index information. Consequently, the plurality of information items can be determined by read from the RFID tag. The plurality of information items may be, for example characteristic information indicative of a characteristic of the thing. At least one each of the selected plurality of information items may be one of a set of predefined values. For example, gender may be male or female, strain may be one of a plurality of known strains.

Embodiments provide a means of storing the plurality of information items in a compressed state, so that much more information can be stored in the RFID tag than otherwise achievable.

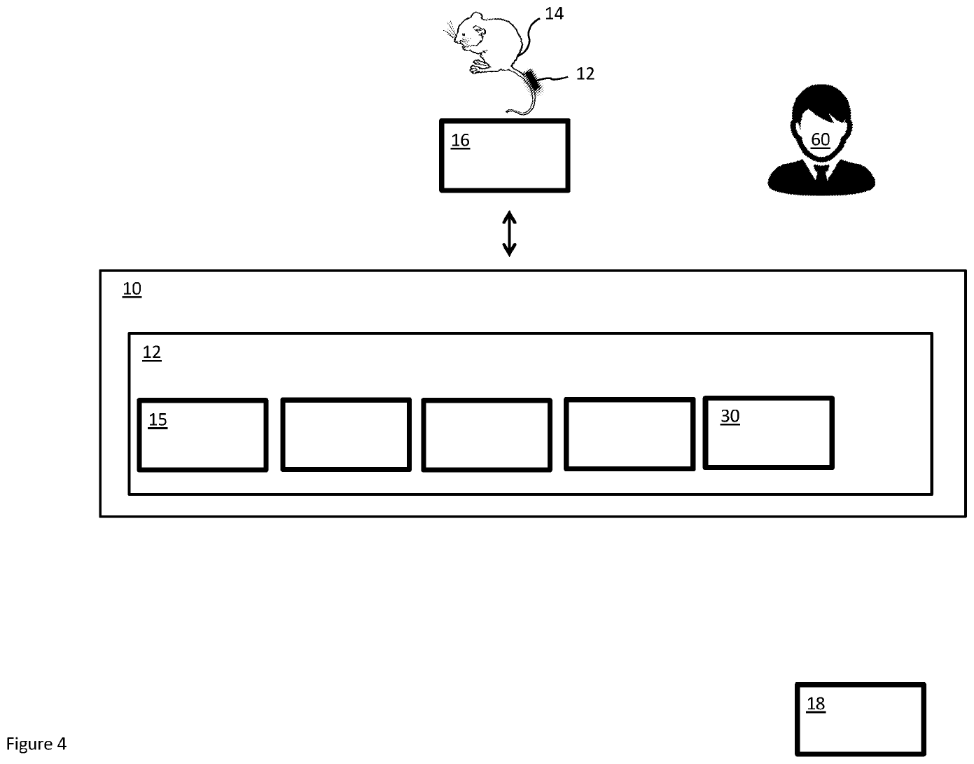

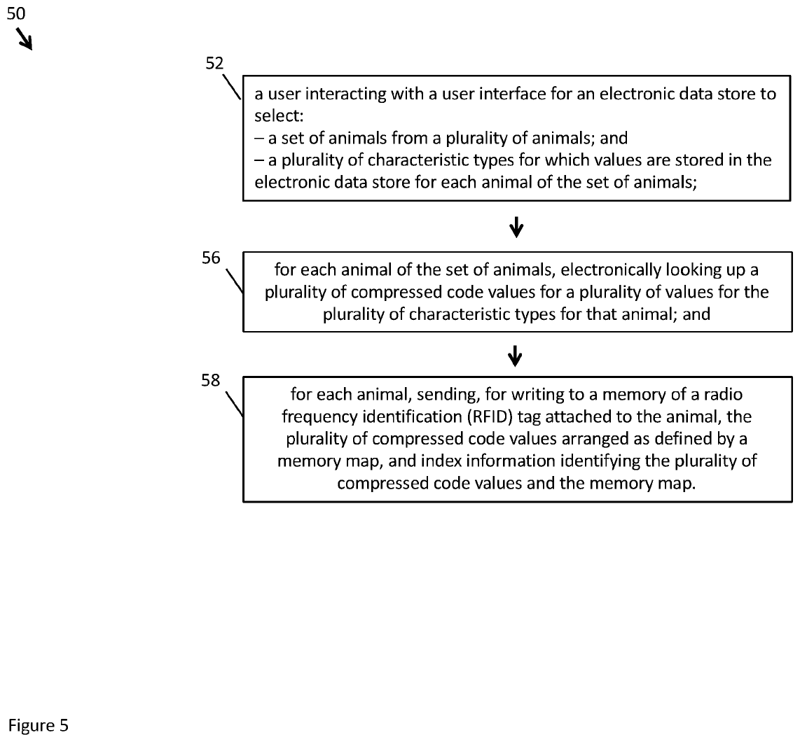

FIG. 4 shows a schematic diagram of another embodiment of a system 10 for storing a plurality of information items on a RFID tag 12, where parts similar or identical to those in FIG. 2 are similarly numbered. The system 10 comprises a user interface 30 for an electronic data store 18. The processor 12 comprises non-transitory processor readable tangible media in the form of flash memory 14 including program instructions which when executed by the processor 12 causes the processor to perform an embodiment of a method 50, a flow chart for which is shown in FIG. 5. In a step 52, a user 60 interacts with a user interface for an electronic data store to select a set of animals from a plurality of animals and a plurality of characteristic types for which values are stored in the electronic data store 18 for each animal of the set of animals. In a step 56, for each animal of the set of animals, a plurality of compressed code values for a plurality of values for the plurality of characteristic types for that animal is electronically determined. In a step 58, for each animal, the plurality of compressed code values and index information identifying the compressed code values and the memory map is sent for writing to the memory of the RFID tag attached to that animal.

The user 60 may interact the user interface to define a tag-write task that is later executed. The user may interact with the user interface to direct the system 10 to execute the task immediately, or specify a time to execute the task, for example “3 pm, this Friday”. Generally, a list of field available to write and the types of field values are predefined. The system 10 may read all the list values in a field and generates a unique hexadecimal, and then a binary mapping code for each list value. For example, for a strain field, the strain field values may be mapped as per the following lookup table:

| Strain | Compressed code value |
|---|---|
| Balb/c | 00 |
| C57BL6 | 01 |
| . . . | . . . |
| ZF1 | 9Z |

For a gender field, the gender value may be mapped as per the following lookup table:

| Gender | Compressed Code Value |
|---|---|
| Male | 0 |
| Female | 1 |

Two character alphanumerical mapping may enable, for example, 1,396 values to be in a stain list. The variable is mapped to a known number of hexadecimal values and therefore a known number of bits. This approach also enables a variable character string length to be stored in RFID tag memory. A three character alphanumeric value enables over 50,000 list values, and four characters enables over one million list values.

Each of the symbols 0 to 9 and A to Z (alphanumeric characters) may be mapped to a binary number, however there is no data compression. With this encoding approach, 128 bits can encode 24 alpha characters or 32 numbers, providing a significant capacity to store many data field values.

Some embodiments create alphanumeric codes as look up values for long lists of values, such as strain. For example, 0A to 9Z can encode 360 unique list values. This coding would require 9 bits to encode, where the first 4 bits are the numbers 0 to 9 and the next 5 bits are the numbers (bit 9 is blank) and alphas A to Z.

In practice, there are over 10,000 strains, but only the large breeders will carry such large numbers in their facilities and by using a precursor code, such as 0/1 for Mouse/Rat and 000-111 for Inbred/Outbred/Transgenic etc. the codes can be common to these categories.

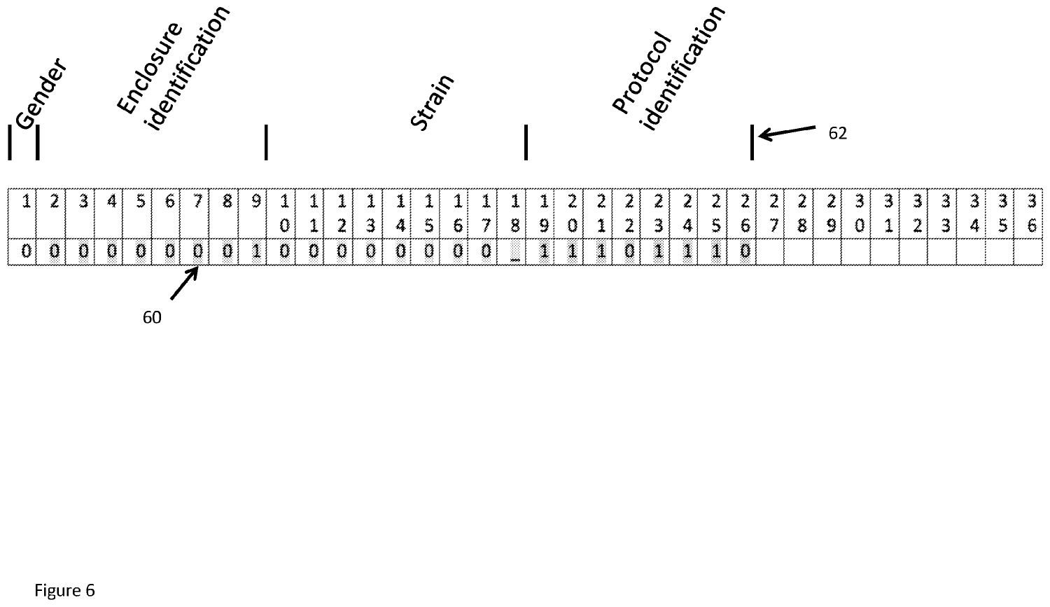

FIG. 6 shows a bit-wise representation of a memory map 60 for a particular selection of information items. Bit position 1 is for gender. Bit positions 2-9 are for enclosure identification. Bit positions 10-18 are for strain code. Bit positions 19-26 are for protocol identification. At least the gender bit positions and strain code bit positions each require a lookup table for information retrieved. Table 1 shows the position of the fields within RFID tag memory for another selection of information items. The information items are Gender, tattoo character 1, tattoo character 2, tattoo character 3, strain ID, data of birth, and protocol identification. At fixed positions is at least one index field comprising index information identifying the memory map and the lookup table that lists the plurality of compress code values against information item values. For example, bit ‘01’ and bit ‘02’ indicate that the map and lookup table (“algorithm”) are customer defined and associated with ‘5’. The memory map and lookup tables associated with the value ‘5’ can be retrieved from memory by the processor 12. The retrieved memory map enables the processor to isolate compressed code value for a field (e.g. gender) and then decode it using the appropriate lookup table for that field.

Because any one of a very large number of lookup tables and memory maps can be used, the type of information stored on an RFID tag is very flexible and can be easily customised.

Information items that comprise an arbitrary length of arbitrary characters can be greatly compressed. For example, each of the 26 expansive volumes of encyclopaedia Britannica may be represented by a different two-digit decimal number or single letter in RFID tag memory.

TABLE 1
Filed positions within RFID tag memory.

| | | | | |
|---|---|---|---|---|
| | Start | Stop | Length | |
| ID | Bit | Bit | [bits] | Description |

Reserved section

| | | | | |
|---|---|---|---|---|
| 01 | 0 | 0 | 1 | Describes the origin of the |
| | | | | encode/decode algorithm. |
| | | | | Manufacturer defined algorithms |
| | | | | are ‘system’ algorithms that are |
| | | | | standard across all customers |
| | | | | and implementations. Customer |
| | | | | defined algorithms can be created |
| | | | | in Passport by the customer and |
| | | | | include the ability to choose the |
| | | | | data encoded onto the chip. |
| | | | | 0 = Manufacturer defined |
| | | | | 1 = Customer defined |
| 02 | 1 | 5 | 5 | Algorithm Id. This allows up to 32 algorithms for |
| | | | | both Somark and a customer. |

Custom data section [Example-Encoding data for a mouse].

| | | | | |
|---|---|---|---|---|
| 03 | 6 | 6 | 1 | Gender 0 = Male 1 = Female |
| 04 | 7 | 12 | 6 | Tattoo character 1 Provides an integer value up to 64. |
| | | | | Requires integer value up to |
| | | | | 35 for one character. See ‘Tattoo Id-Characters’ |
| 05 | 13 | 18 | 6 | Tattoo character 2 Provides an integer value up to 64. |
| | | | | Requires integer value up to |
| | | | | 35 for one character. |
| | | | | See ‘Tattoo Id-Characters’ |
| 06 | 19 | 24 | 6 | Tattoo character 3 Provides an integer value up to 64. |
| | | | | Requires integer value up to |
| | | | | 35 for one character. See ‘Tattoo Id-Characters’ |
| 07 | 25 | 38 | 14 | Strain Id. Lookup into the strain data |
| | | | | table-allows up to 16384 unique |
| | | | | strain values. |
| 08 | 39 | 51 | 13 | Date of birth (calculated). This is the number of days after a |
| | | | | predetermined fixed date (say |
| | | | | Jan. 5, 2017) that the animal was born. |
| | | | | This gives up to 22.4 years |
| | | | | before this value runs out. |
| 09 | 52 | 63 | 12 | Protocol Id Lookup into the protocol data |
| | | | | table-allows up to 4096 unique |
| | | | | protocol values. |

The system 10 is configured to determine whether there is sufficient space in the RFID tag memory to store the selected characteristic types. The system 10 also generates the memory map for the RFID tag memory for storing the plurality of values for the plurality of selected characteristic types. The memory map is stored in processor memory 15 for interpreting information read from an RFID tag 14.

In this but not all embodiments, the memory of each animal's RFID tag may be read by the RFID tag reader 16 to obtain identity information indicative of the identity of the animal 14 to which the RFID tag 12 is attached. The identity information is sent by the RFID tag reader 16. The system 10 receives the identity information and confirms that the plurality of information items are associated with the identity information. When so confirmed, the RFID tag reader is instructed by the system 10 to write the information for that animal on that animal's RFID tag 14.

The plurality of animals are, in this embodiment, experimental subjects, and are located at an animal facility in the form of animal research facility.

Embodiments may write up to the maximum size of information of data to the tag's memory. The tag 12 has 128 bits of electronic product code (EPC) memory and 32 bits of other memory, consequently there is up to 160 bits of data that can be written to the tag. Compression of the selected information enables the values contained in many fields within the animal's record in the data store 18 to be written in the tag's memory.

The processor 12 may be in the form of a computer server connected to a computer network. The electronic interface 18 may comprise, for example, a web page displayed on a user computation device in communication with the computer server via at least the computer network, and in some embodiments an internetwork in the form of, for example, the Internet. The processor 12 may send the information to another intermediate processor, which sends the information to the RFID reader 16.

In an alternative embodiment, the processor 12 comprises computing device in the form of, for example, a general purpose computer (e.g. a personal computer, a laptop etc.), a smart phone, tablet computer or generally any suitable device. The RFID reader 16 may be in communication with the processor 12 via a personal area network, for example a USB or Bluetooth connection, or generally any suitable form of network.

Writing to a RFID tag's memory overwrites it. The processor comprises another data store in which is stored information previously held within RFID tag memory.

In an example, the user interface 30 is configured to enable the user 60 to, for example:
1. Select the rodent to which the data should be written
2. Select the date/time when the data should be written OR simply choose “when Tag is next read”
3. Select from a list of fields from the rodent's record, for example:
   a. Enclosure identification field
   b. Gender field
   c. Date of birth or Age (in days or weeks) field
   d. Strain field
   e. Protocol identification field
   f. Study identification field
   g. Tattoo value field, holding the information tattooed on the animal.
   h. Genotype field
   i. Last recorded weight field

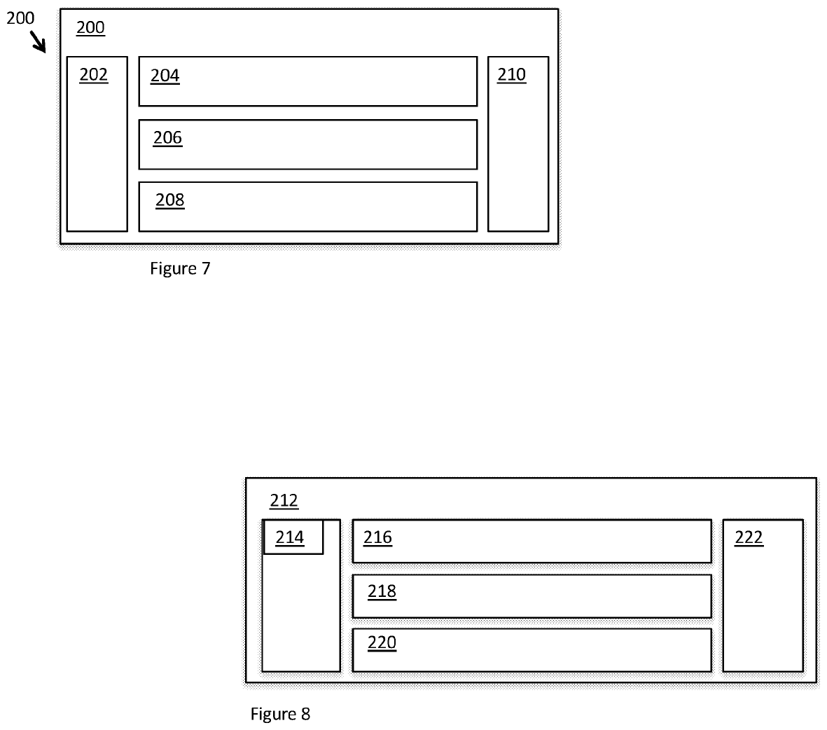

FIG. 7 shows a schematic representation of an example of a suitable computer server architecture, in the form of a cloud virtual server architecture 200, examples of which include AZURE, AMAZON, etc. however a private cloud virtual server may be used. The cloud virtual server has a N tier architecture, in which presentation, application processing, and data management functions may be physically separated. It has a service orientated modular architecture. The architecture 200 includes, but is not necessarily limited to, an integration services module 202, a user interface module 204, a business logic module 206, data storage, access and query module 208, and a security services module 210. The cloud virtual server architecture provides infrastructure services (hosting, DR, storage, CPU, RAM, Firewalls etc.). FIG. 8 shows a schematic diagram of an example of an integration architecture 212 for the cloud virtual server 200. The integration architecture 212 includes a communications network interconnect (e.g. AZURE IOT Hub) 214, a data encryption and decryption module 216, a communications network interface module 218.

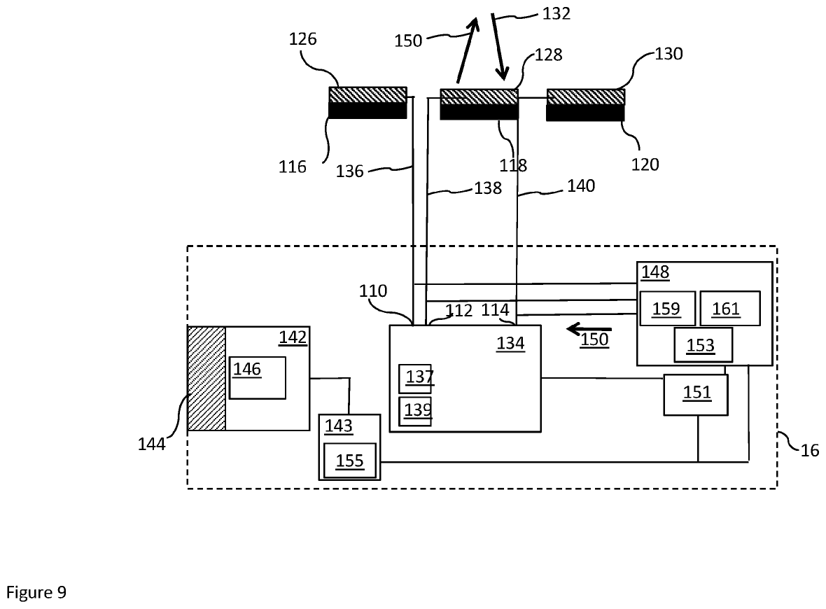

FIG. 9 shows a schematic diagram of an embodiment of the RFID tag reader 16. The RFID tag 12 comprises an integrated circuit comprising non-volatile memory which stores animal identification information, and may also store other information ready for transmission within the radio signal 132. The antenna 126,128, 130 each comprise a fractal antenna, however the antennae may be meander antennae, line antennae or generally any suitable form of antennae. A fractal antenna is an antenna that uses a fractal, self-similar design to maximize the length, or increase the perimeter (on inside sections or the outer structure), of material that can receive or transmit electromagnetic radiation within a given surface area or volume.

The RFID reader 16 has an RFID receiver 134 in signal communication with the RFID antennae 126, 128, 130 of a plurality of RFID tag detection zones 116, 118, 120. The RFID reader 16 is for receiving the radio signal 132 generated by the RFID tag 14 when interrogated. The radio signal 132 is generated according to an air interface protocol which may be any suitable air interface protocol, for example RAIN RFID, and EPC global UHF Class 1 Gen2/ISO 18000-63 (formerly 18000-6C). Signal communications is via electrically conductive pathways in the form of cables 136, 138, 140, or alternatively wires and/or traces for example. The electrically conductive pathways 136, 138, 140 electrically connect the RFID antennae 126, 128 and 130 and the RFID reader 16, and the RFID receiver 134 therein. Cables 136, 138 and 140 are in this embodiment co-axial cables for radio frequencies, for example UHF, received and/or transmitted by the RFID tag 12. The RFID reader 16 has a communication interface 142, which comprises in this embodiment a suitable physical communication interface. In this embodiment the physical communications interface comprises a connector 144 in the form of a data plug (or alternatively a data socket, for example) and associated physical layer circuitry. The communications interface 142 may optionally comprise one or more higher communication layers in communication circuitry 146 (e.g. data link and application layers of the OSI model), or these may be incorporated in the receiver 134 or other subsystem of the reader 16. The communications interface 144 may be for, for example, USB, ETHERNET, THUNDERBOLT, Bluetooth, Wi-Fi or generally any suitable form of communications interfaces and protocols. In the present embodiment, the communications interface 142 is a personal area network (PAN) in the form of a USB interface, specifically a USB 3.0 interface that also provides power.

The receiver 134 comprises an amplifier 137 that amplifies the RFID tag radio signal 132 received via the antennae 126, 128 and 130. The receiver 134 comprises a demodulator 139 that compares the modulated signal to a signal generated by an oscillator 151 of the same carrier frequency, thereby extracting a message from the radio signal 132.

A RFID reader controller 143 is in signal communication with the receiver 134 and interface 142 and which is in the form of a digital signal processor is configured to process the message extracted from the signal 132 by the receiver 134 to obtain the animal identification information, and generate the RFID tag detection zone information. An application specific integrated circuit or generally any suitable logic device may be used in place of the digital signal processor. The RFID controller 143 generally controls communications with middleware and backend systems, runs the primary operation systems for the reader 49, and controls memory usage.

The RFID reader 49 may send a string of symbols comprising, for example, the read information, last seen time for the tag 14, last seen date for the tag 14, first seen time for the tag 14, first seen date for the tag 14, received signal strength indicator (RSSI), Protocol control (PC) and a cyclic redundancy check (CRC).

In the present embodiment, but not all embodiments, when an antenna is activated when adjacently disposed to a plurality of RFID tagged animals, the antenna will capture and transmit to the reader:
The date and time the antenna was activated
The antenna's unique identification (UID)
The read information
Data in the user memory portion of the RFID tag.

The RFID reader 16 comprises an RFID interrogation signal transmitter 148 configured to transmit an RFID interrogation signal 150 to at least one of the RFID antennae 126, 128, 130 of the plurality of RFID tag detection zones 116, 118, 120. The signal is radiated by at least one of the antennae. The RFID interrogation signal 150 uses an air interface protocol which may be any suitable air interface protocol. The RFID interrogation signal transmitter 148 may comprise a base band transmitter 159 to generate the interrogation signal 150, a power amplifier 161 to amplify the carrier signal produced by the oscillator 151 and a modulator 153 to modulate the amplitude, frequency or phase of the carrier signal. While system 110 is monostatic, other embodiments may be bistatic (that is separate antennae for transmitting the interrogation signal 50 and receiving the radio signal 132) or multistatic, for example.

In an alternative embodiment, the RFID reader 149 comprises a host logic device and at least one RFID reader chip in the form of an IMPINJ INDY RS2000 reader chip or generally any suitable form of reader chip. The RS200 has 4 monostatic ports, which may require RFID tag detection zones to be inactive, or the use of more than one RS200 so that more than 4 detection zones may be used, or switches so that more than one antenna can use a port. When using the IMPINJ INDY RS2000 reader chip, a MONZA R6-P RAIN RFID tag chip, for example, may be attached to the animal 14, however generally any suitable RFID tag may be used. The host is in communication with the reader chip via a UART serial interface or generally any suitable interface. The host comprises a RASBERRY PI, however any suitable host may be used, including QUALCOMM Dragonboard 410c, system-on-a-board and microcontrollers, an example of which is the MSP430 IRI-LT host microcontroller.

In the alternative embodiment, the Impinj Indy application called ‘inventory_live’ is modified to select and utilize a specific antenna port, either port 0 or port 1. This creates two new applications called inventory_live_antport0.exe and inventory_live_antport1.exe to read specifically from antenna port 0 and antenna port 1 respectively. To read RFID tags from antenna port 0, the reader 49 executes the inventory_live_antport0.exe application and to read RFID tags from antenna port 1 the reader 49 executes the inventory_live_antport1.exe application.

In the alternative embodiment, the reader 16 comprises a printed circuit board assembly (PCBA) comprising the host logic device, RFID reader chip, and firmware. Traces on the PCB electrically connect the host and the RFID reader chip.

The RFID tag reader 16 is one of a plurality of RFID tag readers. Each of the plurality of RFID tag readers is for locating an animal 12 having attached thereto a radio frequency identification tag 14. Each of the plurality of RFID tag readers is suitable for locating more than one animal in each a plurality of enclosures. Each of the plurality of RFID tag readers 16 are configured to send read information via a personal area network in the form of a Universal Serial Bus (USB 3.0, for example), however any suitable communications channel may be used, examples of which a personal area network (e.g. a Universal Serial Bus network, a BLUETOOTH network, a FireWire network), packet-switched networks, a local area network (e.g. an Ethernet network defined by the standard IEEE 802.3 or a variant thereof, a Wi-Fi network defined by the standard IEEE 802.11 or a variant thereof, a Fibre Channel network), a metropolitan area network, a wide area network (e.g. packet over SONET/SDH, MPLS, Frame Relay), or another meshed radio network, for example, a ZIGBEE network. ASCII or XML encoded data may be sent by the reader 16. Other encoding schemes may be used. The encoded data may be encrypted using, for example, an Advanced Encryption Standard.

In this but not all embodiments, the RFID tag 12 has dimensions of no more than 4 mm long×0.5 mm wide and a thickness of less than 0.3 mm. The RFID tag 12 is passive and comprises a semi-conductor integrated circuit (“RFID tag chip”), however it may take any suitable form. The RFID tag 12 has read/write capabilities and a memory to store data. Generally, the RFID tag may operate at any suitable frequency. In the present embodiment, the RFID tag 14 operates in the Ultra High Frequency (UHF) band (for example, in the range of 860 MHz to 920 MHz), configured to work within the regulated power maximum of 4 watts EIRP. The read distance of the tag 14 may be at least 70 mm. The RFID tag 14 is encapsulated in a bio-inert material in the form of glass, parylene or generally any suitable bio-inert material. An external dipole antenna may be either composed of or coated in a bio-inert highly electrically conductive material or composed of a highly electrically conductive material and coated in a bio-inert material that does not impede electrical conductance. The highly electrically conductive material coating an antenna may be made of a conductive metal, for example copper or silver, or another conductor examples of which include but are not limited to graphite powder or graphene.

Generally, any suitable RFID tag may be used.

Now that embodiments have been described, it will be appreciated that some embodiments may have at least some of the following advantages:
Flexible compressed codes representing arbitrarily large information items may be written on subsequently read.
The information about an animal may be obtained independent of the data store.
The information written to the tag offers a form of “passport” when the tag is implanted in the animal so that when received, the tag memory can be read to confirm its identity, source, genotype and other relevant information which will reduce using the wrong animal in research experiments
The larger number of fields pertaining to the animal enabled by the storage in memory ensures that no access to the data store is needed to validate key information needed to correctly perform laboratory experiments or animal husbandry
The data written to the tag memory provides another data set should the data store information be lost or corrupted, thus enabling work with the animal to continue even when failure of the data store occurs.

Variations and/or modifications may be made to the embodiments described without departing from the spirit or ambit of the invention. For example, while in the described embodiments the the RFID tag 12 is implanted in an animal 14, it may be attached to any other thing, including a non-animate object, for example a shipping container or a good for sale. While in the illustrated system embodiments the data store 18 is external thereof and is in communication therewith, otherwise identical system embodiments comprise the data store 18, for example the processor thereof may comprise the data store 18.

The present embodiments are, therefore, to be considered in all respects as illustrative and not restrictive. Reference to a feature disclosed herein does not mean that all embodiments must include the feature.

Prior art, if any, described herein is not to be taken as an admission that the prior art forms part of the common general knowledge in any jurisdiction.

In the claims which follow and in the preceding description of the invention, except where the context requires otherwise due to express language or necessary implication, the word “comprise” or variations such as “comprises” or “comprising” is used in an inclusive sense, that is to specify the presence of the stated features but not to preclude the presence or addition of further features in various embodiments of the invention.

1. A method comprising the steps of:
electronically selecting a plurality of information items from an electronic data store;
electronically determining a plurality of compressed code values for the electronically selected plurality of information items; and
sending, for writing to a memory of a radio frequency identification (RFID) tag, the plurality of compressed code values arranged as defined by a memory map, and index information identifying the plurality of compressed code values and the memory map.

2. A method defined by claim 1 whereby the plurality of information items are determinable using the plurality of compressed code values arranged as defined by the memory map and the index information.

3. A method defined by either one of claim 1 and claim 2 comprising the step of writing to the RFID tag the plurality of compressed code values arranged as defined by the memory map and the index information.

4. A method defined by any one of the preceding claims wherein the step of electronically determining the plurality of compressed code values comprises the step of electronically looking up a lookup table for the plurality of compressed code values for the electronically selected plurality of information items, the index information identifying the lookup table and the memory map.

5. A method defined by claim 4 comprising the step of reading the plurality of compressed code values and the index information, and retrieving the plurality of information items by looking up the plurality of compressed code values so read in the lookup table identified by the index information so read.

6. A method defined by any one of the preceding claims wherein each of the plurality of information items comprise characteristic information indicative of a characteristic of a thing.

7. A method defined by claim 6 wherein the characteristic information is one of a defined plurality of characteristic information values.

8. A method defined by either one of claim 6 and claim 7 comprising the step of reading identification information from the RFID tag attached to one of a plurality of things and confirming that the identity information is indicative of the identity of the thing.

9. A method defined by any one of the claims 5 to 8 wherein the thing is an animal.

10. A method defined by claim 9 wherein the thing is a non-human animal.

11. A method defined by claim any one of the preceding claims wherein the step of selecting the plurality of information items from an electronic data store comprises the step of a user interacting with a user interface for the electronic data store to select the plurality of information items.

12. A method defined by any one of the preceding claims for storing the plurality of information items on the RFID tag.

13. A method comprising the steps of:
a user interacting with a user interface for an electronic data store to select:
a set of animals from a plurality of animals; and
a plurality of characteristic types for which values are stored in the electronic data store for each animal of the set of animals;
for each animal of the set of animals, electronically looking up a plurality of compressed code values for a plurality of values for the plurality of characteristic types for that animal; and
for each animal, sending, for writing to a memory of a radio frequency identification (RFID) tag attached to the animal, the plurality of compressed code values arranged as defined by a memory map, and index information identifying the plurality of compressed code values and the memory map.

14. A method defined by claim 13 comprising the steps of:
for each animal in the set of animals, reading animal identity information stored in the memory of the attached RFID tag to confirm that animal's identity and subsequently writing to the memory the plurality of compressed code values as arranged as defined by the memory map, and the index information identifying the plurality of compressed code values and the memory map.
